(19) United States
(12) Patent Application Publication
(10) Pub. No.: US 2010/0127339 A1
(43) Pub. Date: May 27, 2010

(54) MICROMECHANICAL COMPONENT HAVING AN ANTI-ADHESIVE LAYER

(76) Inventors: Franz Laermer, Weil Der Stadt (DE); Silvia Kronmueller, Schwaikheim (DE); Tino Fuchs, Tuebingen (DE)

Correspondence Address: KENYON & KENYON LLP, ONE BROADWAY, NEW YORK, NY, 10004, US

(21) Appl. No.: 12/312,165

(22) PCT Filed: Sep. 10, 2007
(86) PCT No.: PCT/EP2007/059448

§ 371 Date: Jan. 27, 2010

(30) Foreign Application Priority Data
Oct. 25, 2006 (DE) 102006050188.8

(51) Int. Cl. H01L 29/84; H01L 21/50

(52) U.S. Cl. 257/415; 438/51; 257/E29.324; 257/E21.499; 977/882

(57) ABSTRACT

A micromechanical component, having a substrate and a functional element, the functional element having a functional surface which has an anti-adhesion layer, that has been applied at least in regions, for reducing the surface adhesion forces, and in which the anti-adhesion layer is stable to a temperature of more than 800° C.

### FIELD OF THE INVENTION

The present invention relates to a micromechanical component and to a method for producing a micromechanical component.

### BACKGROUND INFORMATION

Movable elements in micromechanical patterns or in microelectromechanical patterns or components (so-called MEMS components) are able to adhere or stick to the fixed patterns. Mechanical overloading or electrostatic charging, among other things, come into consideration as disengaging mechanisms for the sticking together or adherence. A critical, because frequently irreversible adhesion is above all aided by chemical bonding, for example van der Waals interactions, ionic interactions, covalent bonds or metallic bonds. Touching surfaces having high surface energy, such as, for instance, silicon surfaces with or without a mask of OH groups, or perhaps a hydrogen-terminated silicon surface, may demonstrate strong bonding forces which then are based, for instance, on ionic interactions or covalent bonds, and hold the two surfaces together. The adhesion described may be prevented or at least reduced by anti-adhesion layers.

Thus, it is discussed in European Patent Publication EP 1 416 064 A2 that one may coat micromechanical patterns using so-called SAM coatings (self-assembled monolayers) made, for example, of alkyltrichlorosilanes, and thereby prevent the probability of adhesion. It is true that such SAM coatings have only limited thermal stability, which greatly limit the thermal budget of subsequent processes, that is, limit the scope of possibly usable temperatures for subsequent processes, especially to below approximately 500° C. This particularly represents a severe restriction for the zero-level packaging processes coming into consideration, such as capping processes. High temperature processes, such as an epitaxial deposition of diaphragm masks, so-called thin-film capping, is no longer possible over such micromechanical patterns coated by using SAM layers, because of the temperature limitations mentioned, because the SAM coating would be destroyed thereby. An additional disadvantage of SAM coatings is their low stability to abrasion, since these layers are made up of only a few atomic or molecular layers (essentially only a molecular plane). If it comes to striking or rubbing against each other of micromechanical patterns coated in this manner, local removal or damage of SAM coatings is observed.

This may lead to an increase in the probability of adhesion during operation, and thus to an increased risk of failure of the system. One additional disadvantage of the known SAM coatings is that it is not possible to carry out bonding processes, such as anodic bonding, on the coated surfaces (and without costly preparatory work such as laser ablation).

### SUMMARY OF THE INVENTION

By contrast, the micromechanical component, according to the present invention, and the method, according to the present invention, for producing a micromechanical component according to the alternative independent claims have the advantage that a substantially increased temperature budget is available for processes following the application or production of the anti-adhesion layer, which brings with it the advantage that subsequent processes, particularly for producing the packaging of the component, are able to be carried out more simply and more cost-effectively, and having higher quality. The fact that the anti-adhesion layer is resistant to, and stable at a temperature of more than about 800° C., and which may be a temperature of more than about 1000° C., and which may particularly be a temperature of more than about 1200° C., especially enables carrying out epitaxial steps following the deposition or production of the anti-adhesion layer. This makes possible cost-saving, so-called zero-level packaging processes (i.e. packaging processes to be carried out by method steps on the substrate wafer itself), such as a thin-film capping process using silicon as capping material, which requires temperatures of about 1000° C. to about 1100° C. during the silicon epitaxy. The use of silicon carbide as a component or as a main component of the anti-adhesion layer makes it advantageously possible for the anti-adhesion layer to be produced comparatively simply as well as using well-established technology, and thereby comparatively cost-effectively.

According to the exemplary embodiments and/or exemplary methods of the present invention, the layer thickness of the anti-adhesion layer may be provided to be between about 1 nanometer and about 1 micrometer, and which may be between about 2 nanometers and about 200 nanometers, and which especially may be between about 5 nanometers and about 50 nanometers. This makes it possible for the anti-adhesion layer to be developed to be especially thin, so that the geometrical dimensions of the functional element influencing the function of the micromechanical component are changed only in an unimportant manner by the anti-adhesion layer. Furthermore, it is advantageously possible, according to the exemplary embodiments and/or exemplary methods of the present invention, to adapt the thickness of the anti-adhesion layer to individual circumstances, especially with respect to the resistance to abrasion and the like, that is required.

According to one first specific embodiment of the component according to the present invention, the micromechanical component may have a mask of the functional element, the mask having closed perforation openings; the anti-adhesion layer being also provided in the areas of the functional surface facing the perforation openings. This ensures an especially great effectiveness of the anti-adhesion layer.

The first specific embodiment of the component, according to the present invention, corresponds to a production method of the micromechanical component in which, in a first step, a patterning is carried out of the functional element, the mask and the perforation openings, in which, in a second step, the anti-adhesion layer is produced on at least one part of the functional surface, and in which, in a third step, the perforation openings are closed. By the choice of the anti-adhesion layer, or rather by the composition of the anti-adhesion layer, it is advantageously prevented, according to the present invention, that the third step brings about a reduction in the effectiveness of the anti-adhesion action of the anti-adhesion layer.

In one anti-adhesion layer made of silicon carbide, the anti-adhesion effect is maintained, particularly by carbon atoms introduced in excess into the anti-adhesion layer, even in such areas onto which small quantities of silicon atoms are subsequently deposited. It is thereby possible, according to the exemplary embodiments and/or exemplary methods of the present invention, that a plurality of packaging processes are able to be combined with the anti-adhesion layer according to the present invention, which, without an anti-adhesion layer according to the present invention would not be accessible, perhaps because, on account of the closing of the perforation openings, at least in those areas of the functional surface facing the perforation openings, the anti-adhesion properties of an anti-adhesion layer, that is not according to the present invention, would be destroyed.

According to a second specific embodiment of the component of the present invention, the mask of the functional element may be provided as a component cap connected to the substrate by a connecting technique. Thereby a stable enclosure of the functional element of the component may be achieved, in a cost-saving manner. This applies particularly in the case in which the component cap is provided having a Pyrex intermediate layer as connecting technique to the substrate.

The second specific embodiment of the component, according to the present invention, corresponds to a production method of the micromechanical component in which, in a first step, a patterning is carried out of the functional element, the mask and the perforation openings, in which, in a second step, the anti-adhesion layer is produced on at least one part of the functional surface, and in which, in a third step, the component cap is connected to the substrate, especially is anodically bonded, for instance, using a Pyrex intermediate layer. By doing this, it is possible to produce a connection between the substrate and the mask directly on the anti-adhesion layer, without costly intermediate steps, such as a laser ablation of the anti-adhesion layer in those areas where a connection of the mask to the substrate of the component is to be carried out.

Exemplary embodiments of the present invention are shown in the drawings and explained in greater detail in the following description.

### BRIEF DESCRIPTION OF THE DRAWINGS

FIG. 1 shows a schematic sectional representation through a micromechanical component according to the present invention, according to a first specific embodiment.

FIG. 2 shows a schematic sectional representation through a precursor pattern of a micromechanical component according to the present invention, as in FIG. 1.

FIG. 3 shows a schematic sectional representation through a micromechanical component according to the present invention, according to a second specific embodiment.

### DETAILED DESCRIPTION

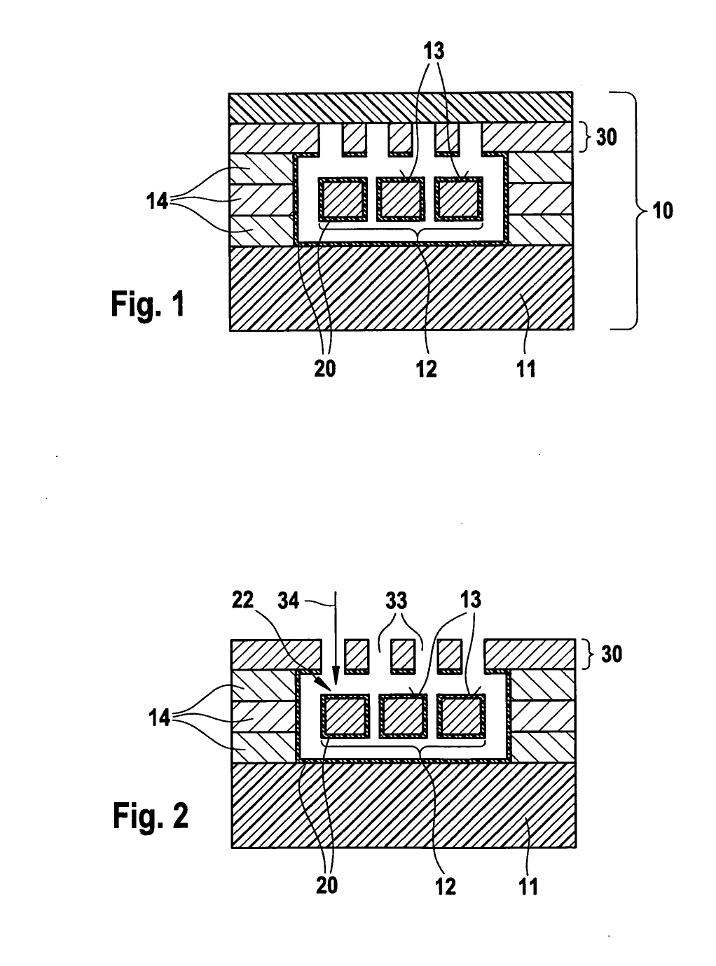

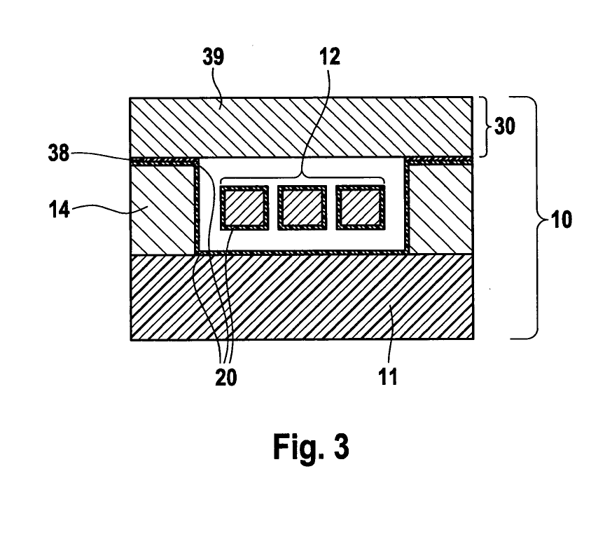

FIG. 1 illustrates a schematic cross-sectional representation through a micromechanical component 10 according to the first specific embodiment of the present invention, and FIG. 3 does the same for a second specific embodiment of the present invention.

In both specific embodiments, component 10 includes a substrate 11, a mask 30 and a micromechanical functional element 12, which is provided to be movable with respect to substrate 11 as well as mask 30. Micromechanical component 10, according to the present invention, is particularly an inertial sensor, perhaps a (linear) acceleration sensor, a yaw-rate sensor or a different micromechanical component having an at least partially movable pattern, perhaps a micromechanical microphone. Functional element 12 is especially a mass element for an inertial sensor, according to the present invention, or a microphone diaphragm or the like. Mask 30 is connected to substrate 11, according to the present invention. However, this does not have to be provided as a direct connection to the substrate material, but may be made via an intermediate layer 14 or via a plurality of intermediate layers 14 which is/are generated during the production of component 10, for instance, by depositing materials to form the functional element or to form a sacrificial layer. On at least one part of surface 13 of functional element 12, an anti-adhesion layer 20 is provided, according to the present invention. This anti-adhesion layer 20 is generated or deposited using a coating method, according to the present invention. In the process, a layer which may be only a few nanometer thick is created as the anti-adhesion layer. In this instance, according to the present invention, it may especially be that silicon carbide of the chemical empirical formula SiₓC₁₋ₓ be provided as the material, or rather the main material.

Such an anti-adhesion layer 20 including silicon carbide is produced or deposited, according to the present invention, in particular using a PECVD process (plasma-enhanced chemical vapor deposition), especially using silane and methane as starting material (so-called precursor) and which may be done using argon as carrier gas. In the process, the anti-adhesion layer is grown on or deposited either amorphously or in microcrystalline fashion, according to the present invention. The layers thus obtained already have many of the advantageous properties known about monocrystalline silicon carbide, such as high chemical, thermal and mechanical stability.

Furthermore, such a layer has an extremely slight adhesion energy for silicon carbide with respect to silicon carbide, or silicon carbide with respect to surfaces coated with silicon carbide. Because of this, according to the present invention, it is particularly advantageously possible to use such a silicon carbide layer as anti-adhesion layer 20. In this connection, it was shown that the anti-adhesion effect of the silicon carbide layers generated using PECVD remain intact unimpaired even when a thermal treatment of the material is carried out at temperatures such as 850° C. and higher, for instance, at 1000° C. and even at 1200° C.

At a temperature beginning at 800° C., since the hydrogen that is unavoidably inserted into the silicon carbide layer during the PECVD process has completely diffused out, nothing changes any more in the anti-adhesion effect or the anti-adhesion property of the silicon carbide layers described, even at even higher temperatures, which makes its use up to extremely high temperatures possible. Alternatively, it is also possible to implement anti-adhesion layer 20 by already generating the coating at the above-mentioned high temperatures, for instance, in high-temperature plasma CVD processes having a very hot substrate electrode at, for example, 600° C. or 850° C. (perhaps as a graphite electrode) or in a so-called LPCVD (low pressure chemical vapor deposition) process or an epitaxial deposition process (perhaps in a tube or RTP reactors), so that one may do without a thermal treatment (subsequent to a deposition), and anti-adhesion layer 20 is able to be applied immediately having the hydrogen-free pattern. In both cases of application of anti-adhesion layer 20, one obtains such a slight surface (adhesion) energy that no, or essentially no tendency to adhesion between similarly coated surfaces can be observed any longer. Therefore, the essential advantage of anti-adhesion layer 20, according to the present invention, compared to the SAM layers known from the related art is the enormous expansion of the thermal working range or the admissible temperature budgets for subsequent process steps up to temperatures far above about 800° C. or even above about 1000° C. or 1200° C., which are typical temperatures for epitaxial depositions.

Among other things, this makes possible cost-saving zero-level packaging processes such as a thin-film capping process (for capping micromechanical patterns), using silicon as the capping material. Furthermore, an anti-adhesion layer 20 according to the present invention is particularly hard and is clearly more resistant to abrasion and more capable of resistance than SAM layers, which clearly reduces the wear-conditioned risk of adhesion during operation. The function of anti-adhesion layer 20 remains fully in good condition even through massive mechanical stresses of anti-adhesion layer 20 by the knocking together of functionally movable and/or fixed patterns. Because of this, it is especially possible, according to the present invention, to reduce component size, and being able thereby to reduce production costs by a lesser chip area being required. Moreover, it is advantageous, according to the present invention, that such an anti-adhesion layer 20 be extraordinarily resistive chemically, and is therefore able to contribute to the passivation of the coated surface in an aggressive environment (for instance, in the presence of aggressive process gases). In addition, silicon carbide is established as a CMOS (complementary metal oxide semiconductor)-compatible material, and is therefore easily integrated into an existing manufacturing environment.

A further advantage of anti-adhesion layer 20, according to the present invention, especially for the first specific embodiment of component 10, according to the present invention, may be seen in FIG. 2. FIG. 2 shows a precursor pattern of a component 10, along with substrate 11, micromechanical functional element 12, intermediate layers 14 and mask 30. Mask 30 is provided as a so-called thin-film capping layer and it includes a plurality of perforation openings 33, which are used particularly for removing a sacrificial layer (not shown) between, for instance, a substrate 11 and functional element 12. For this purpose, through mask 30 an access has to be present to the inside of component 10 (that will later be closed or at least extensively closed) through perforation openings 33. These perforation openings 33, however, always have to be closed again in such thin-film capping processes.

This is usually done, for example, also by a thin-film process, for instance, by a silicon deposition in a reactor (such as a so-called epi-reactor for forming an epitaxial layer) by so-called deposited epitaxial polysilicon (epipolysilicon) or epitaxially deposited monocrystalline silicon. As a consequence of this deposition for sealing perforation openings 33, areas 22 of functional surface 13, that is provided with anti-adhesion layer 20, are also coated of necessity (because of the deposition direction denoted by arrow 34, through perforation openings 33). This applies especially for such areas 22 which are provided facing perforation openings 33. Because of such an undesired coating of anti-adhesion layer 20, a local reduction in the anti-adhesion effect may occur, in that locally the surface adhesion energy is increased again. According to the present invention, it is advantageously provided that one produce anti-adhesion layer 20 in the form of a silicon carbide layer having an excess of carbon. At the high deposition temperatures during the sealing of perforation openings 33, this brings about the formation or maintenance of a carbide-like, for instance again a silicon carbide-like surface, even if, during the sealing step, foreign atoms, such as silicon atoms, are deposited on the silicon carbide layer, that was present before the sealing step, as anti-adhesion layer 20.

Therefore, as long as not too many foreign atoms cover the original silicon carbide surface, and the temperatures are only sufficiently high (in order to effect a sufficiently high mobility of the free carbon and a sufficiently great interdiffusion of the participating silicon atoms and carbon atoms), the excess of carbon atoms in the non-stoichiometrical silicon carbide layer will be sufficient nevertheless to form again and maintain a carbide-like surface in anti-adhesion layer 20 (even in areas 22) having a sufficiently low surface energy. Thus, because of the carbon excess in the anti-adhesion layer, one achieves a “getter effect”, by which the undesired deposited silicon atoms are able to be “gettered”, but neutralized in their harmful effect.

A further advantage of anti-adhesion layer 20, according to the present invention, especially for the second specific embodiment of component 10, according to the present invention, may be seen in FIG. 3. FIG. 3 shows component 10, along with substrate 11, micromechanical functional element 12, intermediate layers 14 and mask 30, according to the second specific embodiment. Mask 30 is developed as a so-called component cap 39, which is connected to substrate 11, or rather indirectly to substrate 11 (for instance, via intermediate layer 14). The advantage is that a high-strength anodic bonding is possible directly and immediately on the silicon carbide. For example, a Pyrex intermediate layer 38 or a Pyrex cap may be bonded directly to the anti-adhesion surface, which is required, for example, in the case of so-called MPT approaches (micropackaging technology), so that these may be implemented cost-effectively.

In particular, using an anti-adhesion layer 20 according to the present invention, it becomes possible to do without a laser treatment before the connecting step between substrate 11 and component cap 39. For this, the silicon carbide layer must be freed from hydrogen in the layer, that is, either at high temperature, for instance, at greater than about 600° C., and which may be greater than about 800° C., it is tempered and the excess hydrogen is driven off from the layer in the process. Alternatively, a hydrogen-free silicon carbide layer may also be deposited at a high temperature of greater than about 600° C., and which may be greater than about 800° C., in an LPCVD method, for example. The anodic bonding is possible because Pyrex demonstrates adhesion to silicon carbide, and during the anodic bonding process, in the bonding interface (that is, in the area of the touching surfaces) liberated oxygen oxidizes the silicon carbide contact surfaces, and in the process, chemical bonds are formed.

1-9. (canceled)

10. A micromechanical component, comprising:
a substrate; and
a functional element having a functional surface that has an anti-adhesion layer, which has been applied at least in regions, for reducing surface adhesion forces;
wherein the anti-adhesion layer is stable to a temperature of more than 800° C.

11. The component of claim 10, wherein the anti-adhesion layer includes silicon carbide.

12. The component of claim 10, wherein a layer thickness of the anti-adhesion layer is between about 1 nanometer and about 1 micrometer.

13. The component of claim 10, wherein the micromechanical component has a mask of the functional element, the mask having perforation openings that are subsequently closed again, and wherein the anti-adhesion layer is provided in areas of the functional surface that face the perforation openings.

14. The component of claim 10, wherein the mask of the functional element is provided as a component cap connected to the substrate.

15. The component of claim 14, wherein the component cap is connected anodically to the substrate as a Pyrex cap or as a component cap having a Pyrex intermediate layer.

16. The component of claim 13, wherein patterning of the functional element, of the mask and of the perforation openings is performed, wherein the anti-adhesion layer is produced on at least one part of the functional surface, and wherein the perforation openings are closed.

17. The component of claim 16, wherein the anti-adhesion layer includes silicon carbide, and wherein during the producing of the anti-adhesion layer, carbon atoms in excess are introduced into the anti-adhesion layer.

18. The method for producing a micromechanical component, the method comprising:
patterning a functional element and a mask;
producing an anti-adhesion layer on at least one part of a functional surface of the functional element; and
connecting a component cap to a substrate;
wherein the micromechanical component includes the substrate, and the functional element which has the functional surface that has the anti-adhesion layer, which has been applied at least in regions, for reducing surface adhesion forces, and wherein the anti-adhesion layer is stable to a temperature of more than 800° C.

19. The method of claim 18, wherein the connecting is performed by anodically bonding the component cap to the substrate.

20. The component of claim 10, wherein a layer thickness of the anti-adhesion layer is between about 2 nanometers and about 200 nanometers.

21. The component of claim 10, wherein a layer thickness of the anti-adhesion layer is between about 5 nanometers and about 50 nanometers.
